(19) United States
(12) Patent Application Publication
(10) Pub. No.: US 2025/0070061 A1
(43) Pub. Date: Feb. 27, 2025

(54) ARRAY SUBSTRATE, DISPLAY PANEL, AND DISPLAY DEVICE

(71) Applicants: Hefei Visionox Technology Co., Ltd., Hefei (CN); KunShan Go-Visionox Opto-Electronics Co., Ltd., Kunshan (CN)

(72) Inventors: Bo YUAN, Hefei (CN); Xijiang ZHANG, Hefei (CN); Jiaoyang LI, Hefei (CN); Bing TAN, Hefei (CN)

(73) Assignees: Hefei Visionox Technology Co., Ltd., Hefei (CN); KunShan Go-Visionox Opto-Electronics Co., Ltd., Kunshan (CN)

(21) Appl. No.: 18/946,925

(22) Filed: Nov. 14, 2024

(30) Foreign Application Priority Data
Dec. 29, 2023 (CN) 202311867957.1

(51) Int. Cl. H01L 23/00; H10K 59/131; H10K 59/40

(52) U.S. Cl. CPC H01L 24/05; H10K 59/131; H01L 2224/05018; H01L 2224/05083; H01L 2224/05558; H01L 2224/05561; H10K 59/40

(57) ABSTRACT

An array substrate, a display panel, and a display device. The array substrate includes a display area, a fan-out area, a bonding area, the fan-out area and the bonding area being arranged at a side of the display area along a first direction, the bonding area being arranged at a side of the fan-out area away from the display area, a substrate, a plurality of signal leads arranged on the substrate and located in the bonding area, and a plurality of pads configured to be electrically connected to a driver integrated circuit. The plurality of pads are stacked on the plurality of signal leads in a one-to-one correspondence and are electrically connected to the plurality of signal leads correspondingly.

### CROSS-REFERENCE TO RELATED APPLICATION

This application claims the priority to Chinese patent application No. 202311867957.1, filed on Dec. 29, 2023, and entitled “Array Substrate, Display Panel, and Display Device”, the contents of which are incorporated herein by reference.

### TECHNICAL FIELD

The present application relates to the technical field of display panels, and in particular to an array substrate, a display panel and a display device.

### BACKGROUND

An organic light emitting diode (OLED) display panel is a hot topic in the research field of display panels at present. The OLED display panel has the advantages of low energy consumption, low cost, self-luminescence, wide viewing angle and fast response speed.

### SUMMARY

In view of this, there is a need to provide an array substrate, a display panel, and a display device.

In a first aspect, the present application presents an array substrate. The array substrate includes: a display area, a fan-out area, a bonding area, a substrate, a plurality of signal leads, and a plurality of pads. The fan-out area and the bonding area are arranged at a side of the display area along a first direction, and the bonding area are arranged at a side of the fan-out area away from the display area. The plurality of signal leads arranged on the substrate and located in the bonding area. The plurality of pads are configured to be electrically connected to a driver integrated circuit (IC), and the plurality of pads are stacked on the plurality of signal leads in a one-to-one correspondence and are electrically connected to the plurality of signal leads correspondingly.

In an embodiment, an orthographic projection of a pad projected on the substrate covers an orthographic projection of a corresponding signal lead projected on the substrate. An outer contour of the orthographic projection of the pad projected on the substrate surrounds an outer contour of the orthographic projection of the corresponding signal lead projected on the substrate.

In an embodiment, the pad includes a first metal layer.

An orthographic projection of the first metal layer projected on the substrate covers the orthographic projection of the corresponding signal lead projected on the substrate.

An outer contour of the orthographic projection of the first metal layer projected on the substrate surrounds the outer contour of the orthographic projection of the corresponding signal lead projected on the substrate.

In an embodiment, a distance between the outer contour of the orthographic projection of the first metal layer projected on the substrate and the outer contour of the orthographic projection of the corresponding signal lead projected on the substrate is in a range from 0.5 μm to 2 μm.

In an embodiment, the distance between the outer contour of the orthographic projection of the first metal layer projected on the substrate and the outer contour of the orthographic projection of the corresponding signal lead projected on the substrate is in a range from 0.5 μm to 1 μm.

In an embodiment, a pad includes a first metal layer, a first insulating layer, and a second metal layer, which are stacked.

In an embodiment, the first metal layer is located at a side of the second metal layer away from or adjacent to the corresponding signal lead.

In an embodiment, the first metal layer is stacked and arranged on the corresponding signal lead, the pad further includes a first insulating layer and a second metal layer which are sequentially stacked and arranged on the first metal layer, and the first metal layer and the second metal layer are electrically connected.

An orthographic projection of the second metal layer projected on the substrate covers the orthographic projection of the first metal layer projected on the substrate.

An outer contour of the orthographic projection of the second metal layer projected on the substrate surrounds the outer contour of the orthographic projection of the first metal layer projected on the substrate.

In an embodiment, a distance between the outer contour of the orthographic projection of the second metal layer projected on the substrate and the outer contour of the orthographic projection of the first metal layer projected on the substrate is in a range from 1 μm to 4 μm.

In an embodiment, a distance between the outer contour of the orthographic projection of the second metal layer projected on the substrate and the outer contour of the orthographic projection of the first metal layer projected on the substrate is in a range from 1.5 μm to 3 μm.

In an embodiment, the first metal layer includes a first portion and a second portion, the first portion is a part of the first metal layer adjacent to the display area, and the second portion is another part of the first metal layer away from the display area.

The first insulating layer overlays the first portion, and the second metal layer overlays the first insulating layer and the second portion of the first metal layer.

In an embodiment, an orthographic projection of the first insulating layer projected on the substrate covers an orthographic projection of the first portion of the first metal layer projected on the substrate. An edge, adjacent to the display area, of the orthographic projection of the first insulating layer projected on the substrate is located between the display area and an edge, adjacent to the display area, of the orthographic projection of the first portion projected on the substrate.

In an embodiment, a distance between the edge, adjacent to the display area, of the orthographic projection of the first insulating layer projected on the substrate and the edge, adjacent to the display area, of the orthographic projection of the first portion projected on the substrate is in a range from 0.1 μm to 3 μm.

In an embodiment, the distance between the edge, adjacent to the display area, of the orthographic projection of the first insulating layer projected on the substrate and the edge, adjacent to the display area, of the orthographic projection of the first portion projected on the substrate is in a range from 0.1 μm to 2 μm.

In an embodiment, a pad includes a first metal layer, a first insulating layer, and a second metal layer, which are stacked. The first metal layer is located at a side of the second metal layer adjacent to a corresponding signal lead. An orthographic projection of the second metal layer projected on the substrate covers at least one of: an orthographic projection of the first insulating layer projected on the substrate, and an orthographic projection of the first metal layer projected on the substrate. An outer contour of the orthographic projection of the second metal layer projected on the substrate surrounds at least one of: an outer contour of the orthographic projection of the first insulating layer projected on the substrate, and an outer contour of the orthographic projection of the first metal layer projected on the substrate.

In an embodiment, a distance between a portion, adjacent to the display area, of the outer contour of the orthographic projection of the second metal layer projected on the substrate and a portion, adjacent to the display area, of the outer contour of the orthographic projection of the first insulating layer projected on the substrate is in a range from 0.4 μm to 2 μm.

In an embodiment, a distance between a portion, adjacent to the display area, of the outer contour of the orthographic projection of the second metal layer projected on the substrate and a portion, adjacent to the display area, of the outer contour of the orthographic projection of the first insulating layer projected on the substrate is in a range from 0.5 μm to 1 μm.

In an embodiment, the array substrate includes a plurality of signal lines located in the display area and a plurality of fan-out leads located in the fan-out area.

A fan-out lead is connected between a signal line and a corresponding signal lead.

In an embodiment, the array substrate further includes a plurality of signal lines and a plurality of fan-out leads, and the plurality of fan-out leads are connected between the plurality of signal lines and the plurality of signal leads in a one-to-one correspondence; the plurality of signal lines, the plurality of fan-out leads and the plurality of signal leads are arranged on the same layer.

In a second aspect, the present application provides a display panel, including the array substrate of any one of the embodiments above.

In an embodiment, the pad includes a first metal layer, a first insulating layer, and a second metal layer, which are stacked, and the first metal layer is located at a side of the second metal layer adjacent to the corresponding signal lead.

The display panel includes a first touch electrode, a second insulating layer, and a second touch electrode, which are stacked. The first metal layer and the first touch electrode are disposed in the same layer. The second metal layer and the second touch electrode are disposed in the same layer.

In an embodiment, the first insulating layer and the second insulating layer are arranged in the same layer.

In a third aspect, a display device is provided and includes the display panel above.

In an embodiment, the display device is foldable; the display area includes a plurality of display sub-areas. The array substrate further includes at least one first foldable area disposed between two adjacent display sub-areas. The display panel has at least one first folding line extending along a second direction. The at least one first foldable area is symmetrically arranged with respect to the at least one first folding line. The first direction and the second direction are perpendicular to each other.

In an embodiment, the display device is foldable; the array substrate further comprises a second foldable area disposed between the bonding area and the display area; the display panel includes a second folding line extending along a second direction. The second foldable area is symmetrically arranged with respect to the second folding line. The first direction and the second direction are perpendicular to each other.

In the technical solutions of the present application, the driver IC may be bonded to the pads, so that signal transmissions between the driver IC and the corresponding signal leads can be realized through the pads.

### BRIEF DESCRIPTION OF THE DRAWINGS

FIG. 1 shows a top view of a display panel (before being bonded to a driver IC) according to an embodiment of the present application.

FIG. 2 shows a schematic sectional view of a display panel cut along a plane perpendicular to a second direction according to an embodiment of the present application.

FIG. 3 shows a schematic sectional view of a bonding area of a display panel cut along a plane perpendicular to the second direction according to an embodiment of the present application.

FIG. 4 shows a schematic sectional view of a bonding area of a display panel cut along a plane perpendicular to the second direction according to another embodiment of the present application.

FIG. 5 shows a schematic sectional view of a display area of a display panel cut along a plane perpendicular to the second direction according to an embodiment of the present application.

FIG. 6 is a schematic structural view showing a plurality of pads according to an embodiment of the present application.

FIG. 7 is a top view showing a plurality of output pads according to an embodiment of the present application.

FIG. 8 shows a top view of a display panel (after being bonded to a driver IC) according to an embodiment of the present application.

FIG. 9 shows a top view of a display panel according to an embodiment of the present application, with a second foldable area being folded.

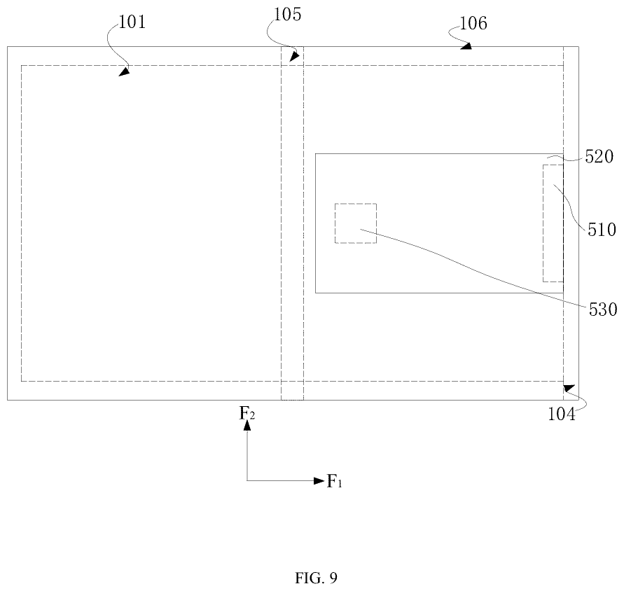

Reference signs: 10, display panel; 101, display area; 1011, display sub-area; 102, fan-out area; 103, bonding area; 104, second foldable area; 105, first foldable area; 106, non-display area; 100, substrate; 110, substrate base; 120, polysilicon display layer; 130, gate medium layer; 140, first driving circuit metal layer; 150, second driving circuit metal layer; 160, third driving circuit metal layer; 170, capacitor medium layer; 180, interlayer medium layer; 190, first planarization layer; 210, signal lead; 220, pad; 221, first metal layer; 2211, first portion; 2212, second portion; 222, first insulating layer; 2221, first side portion; 2222, second side portion; 223, second metal layer; 2231, third portion; 2232, fourth portion; 2201, input pad; 2202, output pad; 2203, redundant pad; 310, source-drain metal layer; 320, second planarization layer; 330, sub-pixel; 331, anode; 340, pixel defining layer; 350, isolating column; 360, encapsulation layer; 410, first touch electrode; 420, second touch electrode; 430, second insulating layer; 440, touch buffer layer; 450, covering layer; 510, driver IC; 520, flexible circuit board; 530, touch IC; J, virtual boundary.

### DETAILED DESCRIPTION OF THE EMBODIMENTS

The present application is described herein in detail with reference to the accompanying drawings in order to make the objectives, features, and advantages of the present application clearer and better understood. In the following description, many specific details are explained to make the present application fully understood. However, the present application can be implemented in many other ways different from those described herein, and those skilled in the art can make similar improvements without departing from the connotation of the present application. Therefore, the present application is not limited by the specific embodiments disclosed hereinafter.

In the description of the present application, it should be understood that the terms “central”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “anticlockwise”, “axial”, “radial”, “circumferential”, etc. indicate the orientations or positional relationships on the basis of the drawings. These terms are only for describing the present application and simplifying the description, rather than indicating or implying that the related devices or elements must have the specific orientations, or be constructed or operated in the specific orientations, and therefore cannot be understood as limitations of the present application.

In addition, the terms “first” and “second” are used merely for description, and cannot be understood as indicating or implying any priority, or indicating the quantity of the element. Therefore, the feature limited by “first” or “second” may explicitly or implicitly includes at least one of the elements. In the description of the present application, “a plurality of” means at least two, such as two, three, etc., unless otherwise specifically defined.

In the present application, unless otherwise clearly specified and defined, the terms “installed”, “connected”, “coupled”, “fixed” and the like should be interpreted broadly. For example, an element may be fixedly connected, detachably connected, or integrated to the other element, may be mechanically connected or electrically connected to the other element, and may be directly connected to the other element or connected to the other element via an intermediate element. Or they may refer to a communication within two elements or an interdependence relationship between two elements, unless otherwise specifically defined. For those of ordinary skill in the art, the specific meanings of the above-mentioned terms in the present application may be understood according to specific circumstances.

In the present application, unless otherwise specifically defined, a first feature, when being referred to as being located “on” or “under” a second feature, may be in direct contact with the other feature or contact the other feature via an intermediate element. Moreover, the first feature, when being referred to as being located “on”, “above”, “over” the second feature, may be located right above or obliquely above the second feature, or merely located at a horizontal level higher than the second feature; the first feature, when being referred to as being located “under”, “below”, “beneath” the second feature, may be located right below or obliquely below the second feature, or merely located at a horizontal level lower than the second feature.

It should be noted that an element, when being referred to as being “fixed” or “attached” to another element, may be fixed or attached to the other element directly or via an intermediate element. An element, when being referred to as being “connected” to another element, may be connected to the other element directly or via an intermediate element. Such terms as “vertical”, “horizontal”, “up”, “down”, “left”, “right” and the like used herein are for illustrative purposes only but do not mean the only way for implementing the present application.

The present application provides an array substrate, a display substrate and a display device, to provide the array substrate that can be electrically connected to a driver IC.

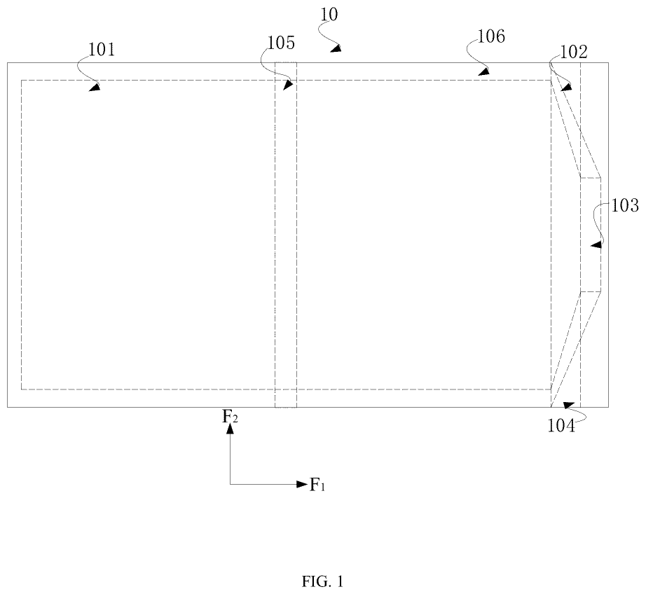

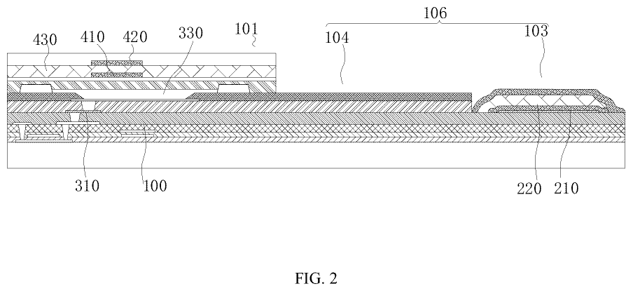

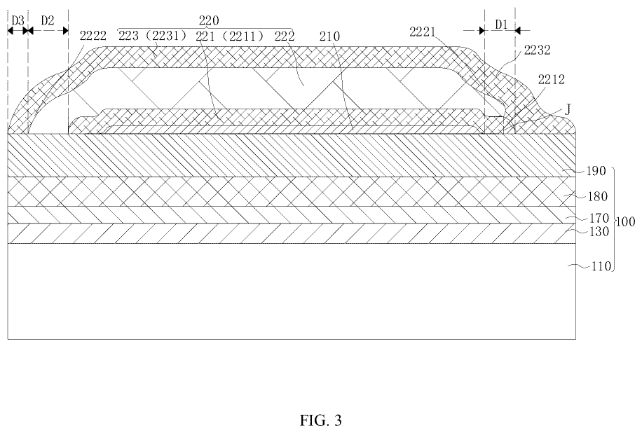

FIG. 1 shows a top view of a display panel 10 according to an embodiment of the present application, FIG. 2 shows a schematic sectional view of a display panel 10 according to an embodiment of the present application, and FIG. 3 shows a schematic sectional view of a bonding area 103 of a display panel 10 cut along a plane perpendicular to a second direction according to an embodiment of the present application.

Referring to FIGS. 1 to 3, according to a first aspect of the present application, an embodiment of the present application provides an array substrate. The array substrate has a display area 101, a fan-out area 102, and a bonding area 103. The fan-out area 102 and the bonding area 103 are arranged at a side of the display area 101 along a first direction F1. The bonding area 103 is arranged at a side of the fan-out area 102 away from the display area 101. The array substrate includes a substrate 100, a plurality of signal leads 210, and a plurality of pads 220. The plurality of pads 220 are configured to be electrically connected to a driver integrated circuit (IC) 510. The plurality of signal leads 210 are arranged on the substrate 100 and located in the bonding area 103. For ease of description, FIG. 1 shows an example of the first direction F1 and the second direction F2, where the first direction F1 is perpendicular to the second direction F2.

The pads 220 are stacked on the signal leads 210 in a one-to-one correspondence and are electrically connected to the corresponding signal leads 210.

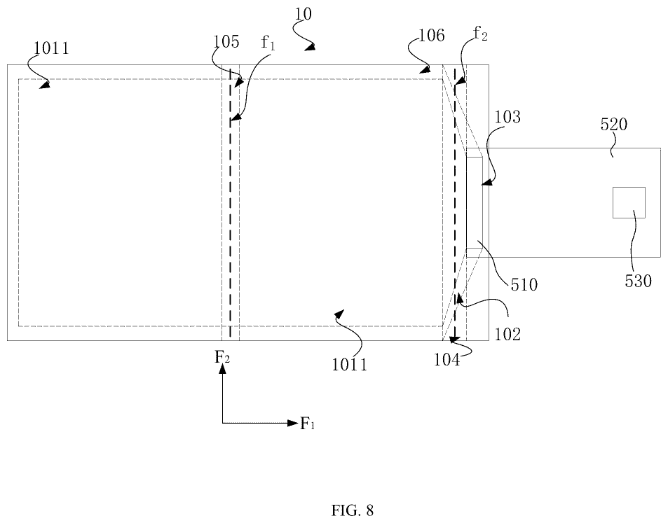

As such, the driver IC 510 may be bonded to the pads 220, so that signal transmissions between the driver IC 510 (shown in FIG. 8) and the corresponding signal leads 210 can be realized through the pads 220.

In some embodiments, an orthographic projection of a pad 220 projected on the substrate 100 covers an orthographic projection of the corresponding signal lead 210 projected on the substrate 100, and an outer contour of the orthographic projection of the pad 220 projected on the substrate 100 surrounds an outer contour of the orthographic projection of the corresponding signal lead 210 projected on the substrate 100.

Specifically, the projection area of the orthographic projection of the pad 220 projected on the substrate 100 is greater than the projection area of the orthographic projection of the corresponding signal lead 210 projected on the substrate 100.

In a conventional pad group of a display panel including a plurality of bonding pads, cracks easily occur at the bonding pads and extend inwards in the bonding pads, thus causing unstable bonding in the conventional display panel.

In the present application, the outer contour of the orthographic projection of the pad 220 projected on the substrate 100 surrounds the outer contour of the orthographic projection of the corresponding signal lead 210 projected on substrate 100. Thus, compared with the conventional bonding pad of the display panel, the outer edge of the pad 220 of the present application is located outside the outer edge of the corresponding signal lead 210, thus preventing the outer edge of the pad 220 and the outer edge of the corresponding signal lead 210 from being concentrated in one position, reducing a stress concentration phenomenon occurring at the connection position between the pad 220 and the corresponding signal lead 210, thereby reducing a probability of cracks occurring in the pad 220, solving the problem of unstable bonding of the pad 220, and improving a yield of the display panel 10.

In some embodiments, as shown in FIG. 3, the pad 220 includes a first metal layer 221. An orthographic projection of the first metal layer 221 projected on the substrate 100 covers an orthographic projection of a corresponding signal lead 210 projected on the substrate 100, and an outer contour of the orthographic projection of the first metal layer 221 projected on the substrate 100 surrounds an outer contour of the orthographic projection of the corresponding signal lead 210 projected on the substrate 100.

Specifically, a projection area of the orthographic projection of the first metal layer 221 projected on the substrate 100 is greater than a projection area of the orthographic projection of the corresponding signal lead 210 projected on the substrate 100.

An outer edge of the first metal layer 221 of the pad 220 is located outside the outer edge of the corresponding signal lead 210, which can prevent the outer edge of the first metal layer 221 of the pad 220 and the outer edge of the corresponding signal lead 210 from being concentrated in one position, thereby reducing the stress concentration phenomenon occurring at the connection position between the first metal layer 221 and the corresponding signal lead 210, reducing the probability of cracks occurring in the pad 220, addressing the problem of unstable bonding of the pad 220, and improving the yield of the display panel 10.

In some embodiments, a distance between the outer contour of the orthographic projection of the first metal layer 221 projected on the substrate 100 and the outer contour of the orthographic projection of the corresponding signal lead 210 projected on the substrate 100 is in a range from 0.5 μm to 2 μm.

Exemplarily, the distance between the outer contour of the orthographic projection of the first metal layer 221 projected on the substrate 100 and the outer contour of the orthographic projection of the corresponding signal lead 210 projected on the substrate 100 may be 0.5 μm, 1.0 μm, 1.5 μm, or 2 μm.

By configuring the distance between the outer contour of the orthographic projection of the first metal layer 221 projected on the substrate 100 and the outer contour of the orthographic projection of the corresponding signal lead 210 projected on the substrate 100 to be within a suitable range, such as from 0.5 μm to 2 μm, the problem of the stress concentration at the connection position between the first metal layer 221 and the corresponding signal lead 210 may be addressed, thereby allowing stress to be more uniformly distributed at the connection position between the first metal layer 221 and the corresponding signal lead 210, reducing the probability of cracks occurring in the pad 220, addressing the problem of unstable bonding of the pad 220, and improving the yield of the display panel 10.

In some embodiments, D1 denotes the distance between the outer contour of the orthographic projection of the first metal layer 221 projected on the substrate 100 and the outer contour of the orthographic projection of the corresponding signal lead 210 projected on the substrate 100, and D1 is in a range from 0.5 μm to 1 μm.

Exemplarily, D1 may be 0.5 μm, 0.8 μm, or 1 μm.

By setting the distance between the outer contour of the orthographic projection of the first metal layer 221 projected on the substrate 100 and the outer contour of the orthographic projection of the corresponding signal lead 210 projected on the substrate 100 in a range from 0.5 μm to 1 μm, not only the stress distribution at the connection position between the first metal layer 221 and the corresponding signal lead 210 can be more uniform, thus reducing the probability of cracks occurring in the pad 220, addressing the problem of unstable bonding of the pad 220, and improving the yield of the display panel 10, but also an occupied size of the pad 220 on the substrate 100 can be reduced, which helps to reduce the volume of the display panel 10.

In some embodiments, the pad 220 includes a first metal layer 221, a first insulating layer 222, and a second metal layer 223, which are stacked. The first metal layer 221 is located at a side of the second metal layer 223 away from the signal lead 210. Alternatively, the first metal layer 221 is located at a side of the second metal layer 223 adjacent to the signal lead 210.

In some embodiments, the first metal layer 221 is stacked and arranged on the signal lead 210, and the pad 220 further includes the first insulating layer 222 and the second metal layer 223, which are sequentially stacked and arranged on the first metal layer 221. The first metal layer 221 is electrically connected to the second metal layer 223. An orthographic projection of the second metal layer 223 projected on the substrate 100 covers an orthographic projection of the first metal layer 221 projected on the substrate 100, and an outer contour of the orthographic projection of the second metal layer 223 projected on the substrate 100 surrounds an outer contour of the orthographic projection of the first metal layer 221 projected on the substrate 100.

Specifically, a projection area of the orthographic projection of the second metal layer 223 projected on the substrate 100 is greater than a projection area of the orthographic projection of the first metal layer 221 projected on the substrate 100.

The first metal layer 221 and the second metal layer 223 may be electrically connected together via a via-hole connection structure. Alternatively, the first insulating layer 222 covers part of the first metal layer 221, and other part of the first metal layer 221 not covered by the first insulating layer 222 and part of the second metal layer 223 may be in contact with each other, thereby forming an electrical connection therebetween.

The outer edge of the second metal layer 223 of the pad 220 is located outside the outer edge of the first metal layer 221 of the pad 220, which may prevent the outer edge of the second metal layer 223 and the outer edge of the first metal layer 221 from being concentrated in one place, thus reducing the stress concentration phenomenon occurring between the second metal layer 223 and the first metal layer 221, reducing the probability of cracks occurring in the pad 220, addressing the problem of unstable bonding of the pad 220, and improving the yield of the display panel 10.

In some embodiments, a distance between the outer contour of the orthographic projection of the second metal layer 223 projected on the substrate 100 and the outer contour of the orthographic projection of the first metal layer 221 projected on the substrate 100 is in a range from 1 μm to 4 μm.

Exemplarily, the distance between the outer contour of the orthographic projection of the second metal layer 223 projected on the substrate 100 and the outer contour of the orthographic projection of the first metal layer 221 projected on the substrate 100 may be 1 μm, 2 μm, 3 μm, or 4 μm.

By configuring the distance between the outer contour of the orthographic projection of the second metal layer 223 projected on the substrate 100 and the outer contour of the orthographic projection of the first metal layer 221 projected on the substrate 100 to be within a suitable range, such as from 1 μm to 4 μm, the problem of the stress concentration between the second metal layer 223 and the first metal layer 221 may be addressed, and the stress distribution between the second metal layer 223 and the first metal layer 221 can be more uniform, thereby reducing the probability of cracks occurring in the pad 220, addressing the problem of unstable bonding of the pad 220, and improving the yield of the display panel 10.

In some embodiments, the distance between the outer contour of the orthographic projection of the second metal layer 223 projected on the substrate 100 and the outer contour of the orthographic projection of the first metal layer 221 projected on the substrate 100 is in a range from 1.5 μm to 3 μm.

Exemplarily, the distance between the outer contour of the orthographic projection of the second metal layer 223 projected on the substrate 100 and the outer contour of the orthographic projection of the first metal layer 221 projected on the substrate 100 may be 1.5 μm, 2 μm, or 3 μm.

By setting the distance between the outer contour of the orthographic projection of the second metal layer 223 projected on the substrate 100 and the outer contour of the orthographic projection of the first metal layer 221 projected on the substrate 100 in a range from 1.5 μm to 3 μm, not only the stress distribution between the second metal layer 223 and the first metal layer 221 can be more uniform, thereby reducing the probability of cracks occurring in the pad 220, addressing the problem of unstable bonding of the pad 220, and improving the yield of the display panel 10, but also the occupied size of the pad 220 on the substrate 100 can be reduced, which helps to reduce the volume of the display panel 100.

In some embodiments, the first metal layer 221 includes a first portion 2211 and a second portion 2212. The first portion 2211 is a part of the first metal layer 221 adjacent to the display area 101, and the second portion 2212 is another part of the first metal layer 221 away from the display area 101. The first insulating layer 222 overlays the first portion 2211, and the second metal layer 223 overlays the first insulating layer 222 and the second portion 2212 of the first metal layer 221.

FIG. 3 shows a virtual boundary J between the first portion 2211 and the second portion 2212. The first portion 2211 is disposed at a side of the virtual boundary J facing the display area 101, and the second portion 2212 is disposed at another side of the virtual boundary J away from the display area 101.

The second portion 2212 is the part of the first metal layer 221 which is not covered by the first insulating layer 222. The second portion 2212 and the second metal layer 223 are in contact with each other and thus electrically connected to each other, which facilitates forming an electrical connection between the pad 220 and the corresponding signal lead 210, and also makes it easy for the driver IC 510 bonded on the pad 220 to realize the signal transmissions with the signal lines located in the display area 101 through the corresponding pad 220.

An orthographic projection of the first insulating layer 222 projected on the substrate 100 covers an orthographic projection of the first portion 2211 of the first metal layer 221 projected on the substrate 100, and an edge, adjacent to the display area 101, of the orthographic projection of the first insulating layer 222 projected on the substrate 100 is located between the display area 101 and an edge, adjacent to the display area 101, of the orthographic projection of the first portion 2211 projected on the substrate 100. In addition, in a direction perpendicular to the first direction F1 and the second direction F2, the orthographic projection of the first portion 2211 projected on the substrate 100 is located within the orthographic projection of the first insulating layer 222 projected on the substrate 100. The size of the orthographic projection of the first portion 2211 projected on the substrate 100 is less than the size of the orthographic projection of the first insulating layer 222 projected on the substrate 100. The edge of the orthographic projection of the first portion 2211 projected on the substrate 100 is spaced apart from the edge of the orthographic projection of the first insulating layer 222 projected on the substrate 100.

Specifically, a projection area of the orthographic projection of the first insulating layer 222 projected on the substrate 100 is greater than a projection area of the orthographic projection of the first portion 2211 of the first metal layer 221 projected on the substrate 100.

The edge, adjacent to the display area 101, of the orthographic projection of the first insulating layer 222 projected on the substrate 100 is located between the display area 101 and the edge, adjacent to the display area 101, of the orthographic projection of the first portion 2211 projected on the substrate 100, and therefore a portion, adjacent to the display area 101, of the outer edge of the first insulating layer 222 is located outside a portion, adjacent to the display area 101, of the outer edge of the first portion 2211 of the first metal layer 221, so that the outer edge of the first insulating layer 222 and the outer edge of the first portion 2211 of the first metal layer 221 may be prevented from being concentrated in one place, thereby reducing the stress concentration phenomenon occurring between the first insulating layer 222 and the first metal layer 221, reducing the probability of cracks occurring in the pad 220, addressing the problem of unstable bonding of the pad 220, and improving the yield of the display panel 10.

In some embodiments, the first portion 2211 and the second portion 2212 are connected along a longitudinal extension direction of the first metal layer 221, namely along the first direction F1. Generally, a length of the first metal layer 221 is greater than a width of the first metal layer 221, where the length of the first metal layer 221 refers to a dimension of the first metal layer 221 along the longitudinal extension direction thereof, namely along the first direction F1, and the width of the first metal layer 221 refers to a dimension of the orthographic projection of the first metal layer 221 projected on the substrate 100, along a direction perpendicular to the longitudinal extension direction of the first metal layer 221, namely along the second direction F2. The second portion 2212 of the first metal layer 221, which is not covered by the first insulating layer 222, is arranged to be located at one side of the first portion 2211 along the longitudinal extension direction of the first metal layer 221, namely along the first direction F1, so that the first metal layer 221 can extend smoothly in the longitudinal extension direction thereof, namely in the first direction F1, thereby reducing the probability of an occurrence of a stress concentration, and further helping to reduce the probability of cracks occurring in the pad 220, addressing the problem of unstable bonding of the pad 220, and improving the yield of the display panel 10.

In some embodiments, a distance between the edge, adjacent to the display area 101, of the orthographic projection of the first insulating layer 222 projected on the substrate 100 and the edge, adjacent to the display area 101, of the orthographic projection of the first portion 2211 projected on the substrate 100 is from 0.1 μm to 3 μm.

Optionally, the distance between the edge, adjacent to the display area 101, of the orthographic projection of the first insulating layer 222 projected on the substrate 100 and the edge, adjacent to the display area 101, of the orthographic projection of the first portion 2211 projected on the substrate 100 is from 0.1 μm to 2 μm.

By configuring the distance between the edge, being adjacent to the display area 101, of the orthographic projection of the first insulating layer 222 projected on the substrate 100 and the edge, being adjacent to the display area 101, of the orthographic projection of the first portion 2211 projected on the substrate 100 to be within a suitable range, such as in a range from 0.1 μm to 3 μm, the problem of the stress concentration at the connection position between the first insulating layer 222 and the first metal layer 221 may be addressed, and the stress distribution at the connection position between the first insulating layer 222 and the first metal layer 221 can be more uniform, thereby reducing the probability of cracks occurring in the pad 220, addressing the problem of unstable bonding of the pad 220, and improving the yield of the display panel 10.

Specifically, the first insulating layer 222 has a first side portion 2221 and a second side portion 2222 which are arranged oppositely. Compared with the second side portion 2222, the first side portion 2221 is closer to the second portion 2212 of the first metal layer 221. D2 denotes a distance between an outer contour of the orthographic projection of the second side portion 2222 projected on the substrate 100, and an edge, adjacent to the display area 101, of the orthographic projection of the first portion 2211 of the first metal layer projected on the substrate 100, and D2 is in a range from 0.5 μm to 3 μm.

That is, compared with the first side portion 2221, the second side portion 2222 is closer to the display area 101.

Exemplarily, D2 may be 0.5 μm, 1 μm, 2 μm, or 3 μm.

By configurating the distance between the outer contour of the orthographic projection of the second side portion 2222 projected on the substrate 100, and the edge, being adjacent to the display area 101, of the orthographic projection of the first portion 2211 projected on the substrate 100 to be within a suitable range, such as from 0.5 μm to 3 μm, the problem of the stress concentration at the connection position between the first insulating layer 222 and the first metal layer 221 may be addressed, and the stress distribution at the connection position between the first insulating layer 222 and the first metal layer 221 can be more uniform, thereby reducing the probability of the cracks occurring in the pad 220, solving the problem of unstable bonding of the pad 220, and improving the yield of the display panel 10.

Optionally, the distance between the outer contour of the orthographic projection of the second side portion 2222 projected on the substrate 100, and the edge, adjacent to the display area 101, of the orthographic projection of the first portion 2211 projected on the substrate 100 is in a range from 1 μm to 2 μm.

In this way, not only the stress distribution at the connection position between the first insulating layer 222 and the first metal layer 221 can be more uniform, thereby reducing the probability of the cracks occurring in the pad 220, addressing the problem of unstable bonding of the pad 220, and improving the yield of the display panel 10, but also the size occupied by the pad 220 on the substrate 100 can be reduced, which helps to reduce the volume of the display panel 10.

In some embodiments, the pad 220 includes a first metal layer 221, a first insulating layer 222, and a second metal layer 223, which are stacked. The first metal layer 221 is located at a side of the second metal layer 223 adjacent to the signal lead 210. The orthographic projection of the second metal layer 223 projected on the substrate 100 covers the orthographic projection of the first insulating layer 222 and/or the orthographic projection of the first metal layer 221 projected on the substrate 100. An outer contour of the orthographic projection of the second metal layer 223 projected on the substrate 100 surrounds an outer contour of the orthographic projection of the first insulating layer 222 and/or an outer contour of the orthographic projection of the first metal layer 221 projected on substrate 100.

For example, the orthographic projection of the second metal layer 223 projected on the substrate 100 covers the orthographic projection of the first insulating layer 222 and the orthographic projection of the first metal layer 221 projected on the substrate 100, respectively, and the outer contour of the orthographic projection of the second metal layer 223 projected on the substrate 100 surrounds the outer contour of the orthographic projection of the first insulating layer 222 and the outer contour of the orthographic projection of the first metal layer 221 projected on the substrate 100, respectively. Alternatively, the orthographic projection of the second metal layer 223 projected on the substrate 100 covers the orthographic projection of the first insulating layer 222 projected on the substrate 100, and the outer contour of the orthographic projection of the second metal layer 223 projected on the substrate 100 surrounds the outer contour of the orthographic projection of the first insulating layer 222 projected on the substrate 100. Alternatively, the orthographic projection of the second metal layer 223 projected on the substrate 100 covers the orthographic projection of the first metal layer 221 projected on the substrate 100, and the outer contour of the orthographic projection of the second metal layer 223 projected on the substrate 100 surrounds the outer contour of the orthographic projection of the first metal layer 221 projected on the substrate 100.

Specifically, the orthographic projection of the second metal layer 223 projected on the substrate 100 covers the orthographic projection of the first insulating layer 222 and the orthographic projection of the first metal layer 221 projected on the substrate 100, and the outer contour of the orthographic projection of the second metal layer 223 projected on the substrate 100 surrounds the outer contour of the orthographic projection of the first insulating layer 222 and the outer contour of the orthographic projection of the first metal layer 221 projected on the substrate 100, respectively. The projection area of the orthographic projection of the second metal layer 223 projected on the substrate 100 is greater than the projection area of the orthographic projection of the first insulating layer 222 projected on the substrate 100.

The outer edge of the second metal layer 223 is located outside the outer edge of the first insulating layer 222, which may prevent the outer edge of the second metal layer 223 and the outer edge of the first insulating layer 222 from being concentrated in one place, thereby reducing the stress concentration phenomenon occurring at the connection position between the second metal layer 223 and the first insulating layer 222, reducing the probability of the cracks occurring in the pad 220, solving the problem of unstable bonding of the pad 220, and improving the yield of the display panel 10.

In some embodiments, the second metal layer 223 includes a third portion 2231 overlaying the top wall of the first insulating layer 222, and a fourth portion 2232 overlaying the circumferential sidewall of the first insulating layer 222, and the third portion 2231 and the fourth portion 2232 are connected with each other.

The second metal layer 223 can be gradually transitioned from the top wall of the first insulating layer 222 to the circumferential sidewall of the first insulating layer 222, so that the second metal layer 223 smoothly extends, thereby addressing the problem of stress concentration, reducing the probability of the cracks occurring in the pad 220, addressing the problem of unstable bonding of the pad 220, and improving the yield of the display panel 10.

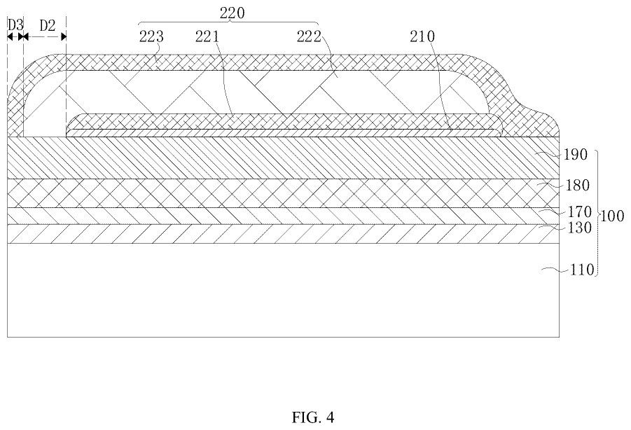

In some embodiments, referring to FIGS. 3 and 4, D3 denotes a distance between a portion, adjacent to the display area 101, of an outer contour of the orthographic projection of the second metal layer 223 projected on the substrate 100 and a portion, adjacent to the display area 101, of an outer contour of the orthographic projection of the first insulating layer 222 projected on the substrate 100. D3 is in a range from 0.4 μm to 2 μm.

Exemplarily, D3 may be 0.4 μm, 1 μm, or 2 μm.

By configuring the distance between the portion, adjacent to the display area 101, of the outer contour of the orthographic projection of the second metal layer 223 projected on the substrate 100 and the portion, adjacent to the display area 101, of the outer contour of the orthographic projection of the first insulating layer 222 projected on the substrate 100 to be within a suitable range, such as from 0.4 μm to 2 μm, the problem of the stress concentration at the connection position between the second metal layer 223 and the first insulating layer 222 can be addressed, and the stress distribution at the connection position between the second metal layer 223 and the first insulating layer 222 can be more uniform, thereby reducing the probability of the cracks occurring in the pad 220, addressing the problem of unstable bonding of the pad 220, and improving the yield of the display panel 10.

Optionally, the distance between the portion, adjacent to the display area 101, of the outer contour of the orthographic projection of the second metal layer 223 projected on the substrate 100 and the portion, adjacent to the display area 101, of the outer contour of the orthographic projection of the first insulating layer 222 projected on the substrate 100 is in a range from 0.5 μm to 1 μm.

In this way, the stress distribution at the connection position between the second metal layer 223 and the first insulating layer 222 may be more uniform, the probability of the cracks occurring in the pad 220 may be reduced, and the problem of unstable bonding of the pad 220 may be addressed, thereby improving the yield of the display panel 10. In addition, the size occupied by the pad 220 on the substrate 100 can be reduced, which helps to reduce the volume of the display panel 10.

In some embodiments, the array substrate includes a signal line located in the active area 101 and a fan-out lead (not shown) located in the fan-out area 102, and the fan-out lead is connected between the signal line and a corresponding signal lead 210.

Optionally, a plurality of signal lines and a plurality of fan-out leads are arranged, and the fan-out leads are connected between the signal lines and the signal leads 210 in a one-to-one correspondence.

In this way, the signal lines located in the display area 101 may be led out from the display area 101 and introduced into the bonding area 103 of the non-display area 106 through the fan-out leads, thus allowing the fan-out leads to be gathered in the bonding area 103 conveniently, and helping to reduce the size of the display panel 10 to some extent.

Optionally, the signal lines, the fan-out leads and the signal leads 210 are arranged in the same layer.

In this way, during the manufacture of the display panel 10, the fan-out leads, the signal leads 210, and the signal lines can be formed at a same step, thereby reducing the manufacturing cost of the display panel 10.

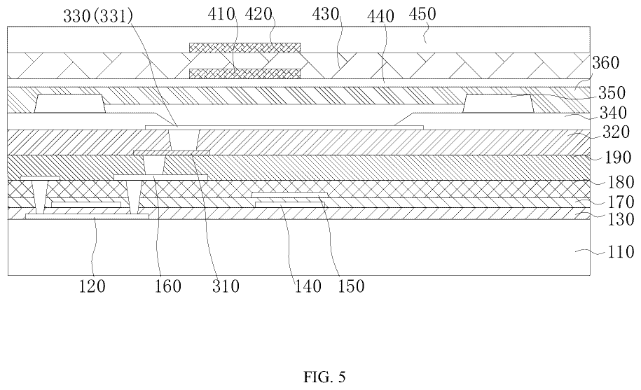

Optionally, referring to FIG. 5, the signal lines may include a source-drain metal layer 310, and may further include a third driving circuit metal layer 160 located below the source-drain metal layer 310. In the present embodiment, the signal lines can include the source-drain metal layer 310. The source-drain metal layer 310 includes a drain electrically connected to an anode 331 of a sub-pixel 330 located in the display area 101, so that the driver IC 510 may be electrically connected to the anode 331 of the sub-pixel 330 through the pad 220, to provide a corresponding signal (such as a high-level signal) to the sub-pixel 330.

In some embodiments, referring to FIG. 5, the substrate 100 includes a substrate base 110, a polysilicon display layer 120, a gate medium layer 130, a first driving circuit metal layer 140, a second driving circuit metal layer 150, a third driving circuit metal layer 160, a capacitor medium layer 170, an interlayer medium layer 180, and a first planarization layer 190, which are stacked.

The gate medium layer 130 is disposed on the substrate base 110 and overlays the polysilicon display layer 120. The first driving circuit metal layer 140 is disposed on the gate medium layer 130. The capacitor medium layer 170 overlays the first driving circuit metal layer 140. The second driving circuit metal layer 150 is disposed on the capacitor medium layer 170. The interlayer medium layer 180 overlays the second driving circuit metal layer 150. The third driving circuit metal layer 160 is disposed on the interlayer medium layer 180, and the first planarization layer 190 overlays the third driving circuit metal layer 160.

The first driving circuit metal layer 140 includes a first capacitor, and the second driving circuit metal layer 150 includes a second capacitor.

In this way, the polysilicon display layer 120 is electrically isolated from the first driving circuit metal layer 140 by the gate medium layer 130, and the first driving circuit metal layer 140 is electrically isolated from the second driving circuit metal layer 150 by the capacitor medium layer 170, and that is, the first capacitor is isolated from the second capacitor by the capacitor medium layer 170.

In a second aspect, the present application provides a display panel 10 including the array substrate of any one of the embodiments above.

In some embodiments, referring to FIG. 2 and FIG. 5, the display panel 10 includes a first touch electrode 410, a second insulating layer 430, and a second touch electrode 420, which are stacked. The first metal layer 221 and the first touch electrode 410 are disposed in the same layer, and the second metal layer 223 and the second touch electrode 420 are disposed in the same layer.

During the manufacture of the display panel 10, the first metal layer 221 and the first touch electrode 410 can be formed at the same time, and the second metal layer 223 and the second touch electrode 420 can be formed at a same step, thereby reducing the manufacturing cost of the display panel 10, and reducing the thickness of the display panel 10 to better meet the requirements of users.

Optionally, the first insulating layer 222 and the second insulating layer 430 are arranged in the same layer.

During the manufacture of the display panel 10, the first insulating layer 222 and the second insulating layer 430 can be formed at a same step, thereby reducing the manufacturing cost of the display panel 10.

In some embodiments, referring to FIG. 5, the array substrate further includes a source-drain metal layer 310 and a second planarization layer 320, which are stacked on the substrate 100. The display panel 10 further includes a pixel defining layer 340, a plurality of isolating columns 350, and an encapsulation layer 360, which are stacked on the array substrate. The display panel 10 further includes sub-pixels 330, and each of the sub-pixels 330 includes an anode 331, a light-emitting layer, and a cathode. The anode 331 is disposed on the second planarization layer 320, and the pixel defining layer 340 is disposed on the second planarization layer 320 and covers the anode 331. The pixel defining layer 340 has a plurality of pixel openings each exposing part of an anode 331. The pixel openings may be in a one-to-one correspondence with the sub-pixels 330, and the light-emitting layer and the cathode of the sub-pixel 330 are arranged in a corresponding pixel opening. A plurality of isolating columns 350 are arranged at intervals in the pixel defining layer 340, and each pixel opening is formed between two adjacent isolating columns 350. The encapsulation layer 360 is arranged on the pixel defining layer 340 and overlays the plurality of sub-pixels 330 and the plurality of isolating columns 350.

Optionally, referring to FIG. 5, the display panel 10 further includes a touch buffer layer 440 covering the encapsulation layer 360, so that the first touch electrode 410 formed on the touch buffer layer 440 is flat. The second insulating layer 430 covers the first touch electrode 410, and the second touch electrode 420 is arranged on the second insulating layer 430, so that the first touch electrode 410 can be electrically isolated from the second touch electrode 420 by the second insulating layer 430. One of the first touch electrode 410 and the second touch electrode 420 may be used as a touch sending electrode, and the other of the first touch electrode 410 and the second touch electrode 420 may be used as a touch receiving electrode, so that a mutual capacitance touch is formed by the first touch electrode 410 and the second touch electrode 420.

Optionally, the display panel 10 further includes a covering layer 450 overlaying the second touch electrode 420. The covering layer 450 may planarize the entire display panel 10 and well protect the first touch electrode 410 and the second touch electrode 420.

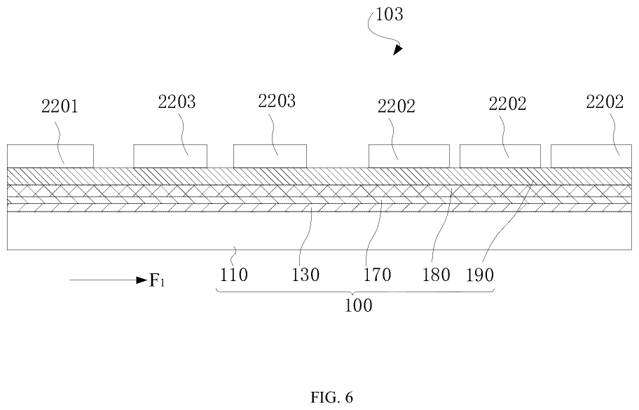

In some embodiments, referring to FIG. 6, the plurality of pads 220 include a plurality of input pads 2201, a plurality of output pads 2202, and a plurality of redundant pads 2203. The plurality of input pads 2201, the plurality of output pads 2202, and the plurality of redundant pads 2203 are arranged in an array.

Each input pad 2201 is electrically connected to an output end of the driver IC 510, and each output pad 2202 is electrically connected to an input end of the driver IC 510, so that the driver IC 510 may be electrically connected to the sub-pixels 330 located in the display area 101 to achieve a signal input and a signal output.

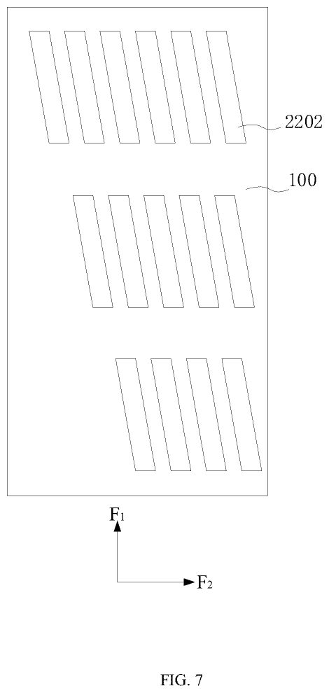

Referring to FIG. 7, the plurality of output pads 2202 are taken as an example for description. The plurality of output pads 2202 are arranged in columns along the first direction F1, and arranged in rows along the second direction F2 intersecting with the first direction F1. Specifically, the first direction F1 is perpendicular to the second direction F2. Exemplarily, the first direction F1 is parallel to the length direction of the display panel 10, and the second direction F2 is parallel to the width direction of the display panel 10. In another embodiment, the second direction F2 is parallel to the length direction of the display panel 10, and the first direction F1 is parallel to the width direction of the display panel.

Such an arrangement facilitates the layout of the fan-out leads, and is conductive to effective utilization of the occupied volume of the display panel 10, thus helping to reduce the volume of the display panel 10 to some extent.

In a third aspect, the present application provides a display device including the display panel 10 of any one of the embodiments in the second aspect.

The display device may be a mobile or fixed terminal having a display panel 10, such as a mobile phone, a television, a tablet computer, a notebook computer, an ultra-mobile personal computer (UMPC), a personal digital assistant (PDA), a navigation device, a smart watch, a virtual reality device, or the like.

The display device provided by the embodiment of the present application includes the display panel 10 above, which can address the problem of unstable bonding of the pad 220 and improve the yield of the display panel 10.

Referring to FIGS. 1 and 8, in some embodiments, the display device is foldable, and the display panel 10 has a first folding line f₁ extending along the second direction F2, where the first direction F1 and the second direction F2 are perpendicular to each other.

The first direction F1 is parallel to the length direction of the display panel 10, and the second direction F2 is parallel to the width direction of the display panel 10. In another embodiment, the second direction F2 is parallel to the length direction of the display panel 10, and the first direction F1 is parallel to the width direction of the display panel.

Specifically, referring to FIG. 1 and FIG. 8, the display area 101 includes a plurality of display sub-areas 1011, and the array substrate further includes a first foldable area 105 disposed between two adjacent display sub-areas 1011, and the first foldable area 105 is symmetrically arranged with respect to the first folding line f₁.

The display device may be folded with respect to the first folding line f₁, which is beneficial for folding and storing the display device.

In some embodiments, referring to FIG. 1 and FIG. 8, the display panel 10 has a second folding line f₂ extending along the second direction F2. Specifically, the array substrate further has a second foldable area 104. The second foldable area 104 is located between the bonding area 103 and the display area 101. The second foldable area 104 is symmetrically arranged with respect to the second folding line f₂.

In this way, the second foldable area 104 may be folded with respect to the second folding line, so that the display panel 10 can be folded with respect to the second folding line f₂. The touch IC 530 and the flexible circuit board 520 may be sequentially arranged on the back side of the substrate 100, which helps to reduce the dimension of the display panel 10 along the first direction F1 and to narrow the frame of the display panel 10.

The display panel 10 further includes the driver IC 510. The driver IC 510 includes a plurality of pins in a one-to-one correspondence with the pads 220. The pads 220 are electrically connected to the corresponding pins, and the pads 220 may be electrically connected to the corresponding pins by using an anisotropic conductive adhesive film. The display panel 10 further includes the flexible circuit board 520, and includes the touch IC 530 disposed at a side of the flexible circuit board 520 away from the pad 220. The flexible circuit board 520 is electrically connected to the touch IC 530 and the driver IC 510, respectively. Each of the first touch electrode 410 and the second touch electrode 420 is electrically connected to the flexible circuit board 520. The light emission of the display area 101 may be controlled through the driver IC 510, and the touch signals collected by the first touch electrode 410 and second touch electrode 420 may be detected through the touch IC 530.

The technical features of the above-mentioned embodiments can be combined arbitrarily. In order to make the description concise, not all possible combinations of the technical features in the embodiments are described. However, as long as there is no contradiction in the combination of these technical features, the combinations should be considered as in the scope of the present disclosure.

The above-described embodiments are only several implementations of the present disclosure, and the descriptions thereof are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims.

What is claimed is:

1. An array substrate, comprising:
a display area;
a fan-out area;
a bonding area, the fan-out area and the bonding area being arranged at a side of the display area along a first direction, the bonding area being arranged at a side of the fan-out area away from the display area;
a substrate;
a plurality of signal leads arranged on the substrate and located in the bonding area; and
a plurality of pads configured to be electrically connected to a driver integrated circuit, the plurality of pads being stacked on the plurality of signal leads in a one-to-one correspondence and being electrically connected to the plurality of signal leads correspondingly.

2. The array substrate according to claim 1, wherein
an orthographic projection of a pad on the substrate covers an orthographic projection of a corresponding signal lead on the substrate; and
an outer contour of the orthographic projection of the pad on the substrate surrounds an outer contour of the orthographic projection of the corresponding signal lead on the substrate.

3. The array substrate according to claim 2, wherein
the pad comprises a first metal layer;
an orthographic projection of the first metal layer on the substrate covers the orthographic projection of the corresponding signal lead on the substrate; and
an outer contour of the orthographic projection of the first metal layer on the substrate surrounds the outer contour of the orthographic projection of the corresponding signal lead on the substrate.

4. The array substrate according to claim 3, wherein
a distance between the outer contour of the orthographic projection of the first metal layer on the substrate and the outer contour of the orthographic projection of the corresponding signal lead on the substrate is in a range from 0.5 μm to 2 μm; or
the distance between the outer contour of the orthographic projection of the first metal layer on the substrate and the outer contour of the orthographic projection of the corresponding signal lead on the substrate is in a range from 0.5 μm to 1 μm.

5. The array substrate according to claim 1, wherein
a pad comprises a first metal layer, a first insulating layer, and a second metal layer, which are stacked; and
the first metal layer is located at a side of the second metal layer away from or adjacent to a corresponding signal lead.

6. The array substrate according to claim 3, wherein
the first metal layer is stacked and arranged on the corresponding signal lead, the pad further comprises a first insulating layer and a second metal layer which are sequentially stacked and arranged on the first metal layer, and the first metal layer and the second metal layer are electrically connected to each other;
an orthographic projection of the second metal layer on the substrate covers the orthographic projection of the first metal layer on the substrate; and
an outer contour of the orthographic projection of the second metal layer on the substrate surrounds the outer contour of the orthographic projection of the first metal layer on the substrate.

7. The array substrate according to claim 6, wherein
a distance between the outer contour of the orthographic projection of the second metal layer on the substrate and the outer contour of the orthographic projection of the first metal layer on the substrate is in a range from 1 μm to 4 μm; or
a distance between the outer contour of the orthographic projection of the second metal layer on the substrate and the outer contour of the orthographic projection of the first metal layer on the substrate is in a range from 1.5 μm to 3 μm.

8. The array substrate according to claim 6, wherein
the first metal layer comprises a first portion and a second portion, the first portion is a part of the first metal layer adjacent to the display area, and the second portion is another part of the first metal layer away from the display area; and
the first insulating layer overlays the first portion, and the second metal layer overlays the first insulating layer and the second portion of the first metal layer.

9. The array substrate according to claim 8, wherein
an orthographic projection of the first insulating layer on the substrate covers an orthographic projection of the first portion of the first metal layer on the substrate; and
an edge, adjacent to the display area, of the orthographic projection of the first insulating layer on the substrate is located between the display area and an edge, adjacent to the display area, of the orthographic projection of the first portion on the substrate.

10. The array substrate according to claim 9, wherein
a distance between the edge, adjacent to the display area, of the orthographic projection of the first insulating layer on the substrate and the edge, adjacent to the display area, of the orthographic projection of the first portion on the substrate is in a range from 0.1 μm to 3 μm; or
the distance between the edge, adjacent to the display area, of the orthographic projection of the first insulating layer on the substrate and the edge, adjacent to the display area, of the orthographic projection of the first portion on the substrate is in a range from 0.1 μm to 2 μm.

11. The array substrate according to claim 1, wherein
a pad comprises a first metal layer, a first insulating layer, and a second metal layer, which are stacked;
the first metal layer is located at a side of the second metal layer adjacent to a corresponding signal lead;
an orthographic projection of the second metal layer on the substrate covers at least one of:
an orthographic projection of the first insulating layer on the substrate, and an orthographic projection of the first metal layer on the substrate; and
an outer contour of the orthographic projection of the second metal layer on the substrate surrounds at least one of: an outer contour of the orthographic projection of the first insulating layer on the substrate, and an outer contour of the orthographic projection of the first metal layer on the substrate.

12. The array substrate according to claim 11, wherein
a distance between a portion, adjacent to the display area, of the outer contour of the orthographic projection of the second metal layer on the substrate and a portion, adjacent to the display area, of the outer contour of the orthographic projection of the first insulating layer on the substrate is in a range from 0.4 μm to 2 μm; or
a distance between a portion, adjacent to the display area, of the outer contour of the orthographic projection of the second metal layer on the substrate and a portion, adjacent to the display area, of the outer contour of the orthographic projection of the first insulating layer on the substrate is in a range from 0.5 μm to 1 μm.

13. The array substrate according to claim 1, comprising a plurality of signal lines located in the display area and a plurality of fan-out leads located in the fan-out area; and
a fan-out lead is connected between a signal line and a corresponding signal lead.

14. The array substrate according to claim 1, further comprising:
a plurality of signal lines and a plurality of fan-out leads, wherein the plurality of fan-out leads are connected between the plurality of signal lines and the plurality of signal leads in a one-to-one correspondence;
the plurality of signal lines, the plurality of fan-out leads, and the plurality of signal leads are arranged in the same layer.

15. A display panel, comprising the array substrate according to claim 1.

16. The display panel according to claim 15, wherein:
the pad comprises a first metal layer, a first insulating layer, and a second metal layer, which are stacked, and the first metal layer is located at a side of the second metal layer adjacent to the corresponding signal lead; and
the display panel comprises a first touch electrode, a second insulating layer, and a second touch electrode, which are stacked; the first metal layer and the first touch electrode are disposed in the same layer; and the second metal layer and the second touch electrode are disposed in the same layer.

17. The display panel according to claim 16, wherein the first insulating layer and the second insulating layer are arranged in the same layer.

18. A display device, comprising the display panel according to claim 15.

19. The display device according to claim 18, wherein:
the display device is foldable; the display area comprises a plurality of display sub-areas; the array substrate further comprises at least one first foldable area disposed between two adjacent display sub-areas; the display panel has at least one first folding line extending along a second direction;
the at least one first foldable area is symmetrically arranged with respect to the at least one first folding line; and
the first direction and the second direction are perpendicular to each other.

20. The display device according to claim 18, wherein:
the display device is foldable; the array substrate further comprises a second foldable area disposed between the bonding area and the display area; the display panel comprises a second folding line extending along a second direction;
the second foldable area is symmetrically arranged with respect to the second folding line; and
the first direction and the second direction are perpendicular to each other.
